(19) United States
(12) Patent Application Publication
(10) Pub. No.: US 2013/0105192 A1
(43) Pub. Date: May 2, 2013

(54) PROTECTIVE COVER MECHANISM AND ELECTRONIC DEVICE USING SAME

(71) Applicant: XIAN-WU HUANG, Shenzhen City (CN)

(72) Inventor: XIAN-WU HUANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City, (CN)

(21) Appl. No.: 13/597,591

(22) Filed: Aug. 29, 2012

(30) Foreign Application Priority Data
Oct. 31, 2011 (CN) 201110337347.1

(51) Int. Cl. H05K 5/00

(52) U.S. Cl. 174/50

(57) ABSTRACT

A cover mechanism for an electronic device includes a protective cover and a support member. The support member is latched to the electronic device, and defines two slots. A plurality of projections formed in each slot. The protective cover includes a cover portion, and two axles. The axles are rotatably received in the slots. Each axle includes four ridges. The four ridges of the protective cover are deformedly latched in the slots to position the protective cover relative to the support member in different positions.

### BACKGROUND

1. Technical Field

The present disclosure relates to protective cover mechanisms used in electronic devices (e.g., mobile phones).

2. Description of Related Art

Electronic devices usually have external interfaces (e.g., universal serial bus (USB)) for electrically connecting external devices (e.g., printers), accessories (e.g., USB flash drives) or other electronic devices. Such external interfaces are usually protected by cover mechanisms from e.g., dust or water, to maintain proper functioning.

The cover mechanisms usually include covers with locks. The covers are typically locked to the electronic devices by latches to cover the area through which the interfaces of electronic devices are exposed. However, the covers are not often permanently attached to the electronic device. Thus, the covers may easily be misplaced or lost when not locked to the electronic devices.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present cover mechanism. Moreover, in the drawings, like reference numerals designate corresponding parts throughout the several views.

FIG. 1 is an exploded, isometric view of an exemplary protective cover mechanism used in an electronic device.

FIG. 2 is similar to FIG. 1, but shown from another aspect.

FIG. 3 is an enlarge view of the support member in FIG. 1.

FIG. 4 is an assembled, isometric view of an exemplary cover mechanism, showing the protective cover covering the housing.

FIG. 5 is a partially assembled, isometric view of the cover mechanism shown in FIG. 1.

FIG. 6 is an assembled, isometric view of the exemplary cover mechanism shown in FIG. 1, showing the protective cover rotated to an open position.

FIG. 7 is a cross-sectional view of the cover mechanism of FIG. 4 taken along line VII-VII.

FIG. 8 is a cross-sectional view of the cover mechanism of FIG. 6 taken along line VIII-VIII.

FIG. 9 is a cross-sectional view of the cover mechanism of FIG. 6 taken along line IX-IX.

### DETAILED DESCRIPTION

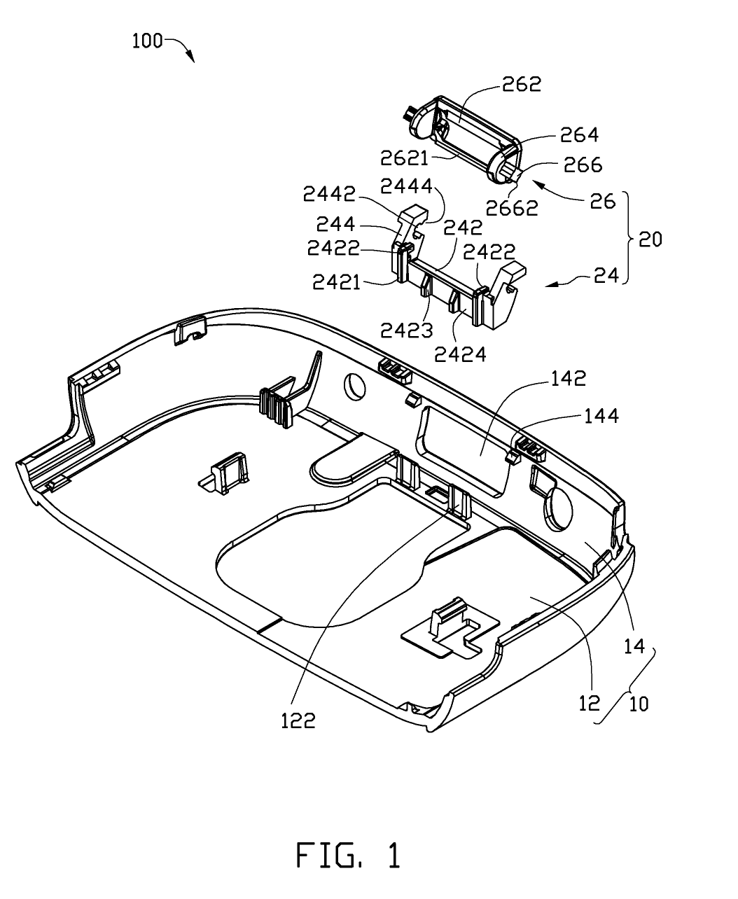

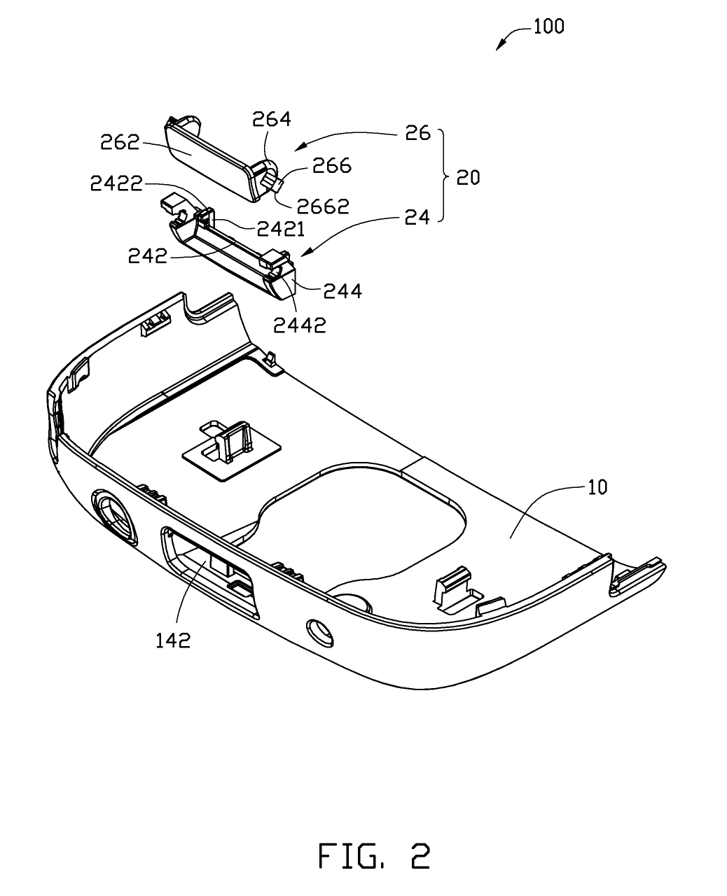

Referring to FIGS. 1 and 2, an exemplary embodiment of a protective cover mechanism 20 is shown. The protective cover mechanism 20 is used with an electronic device 100, such as a mobile phone.

The electronic device 100 includes a housing 10. The housing 10 includes a main body 12 and a sidewall 14 extending from a peripheral edge of the main body 12. Two spaced resisting members 122 protrude from the main body 12, and are spaced from the sidewall 14. The sidewall 14 defines a rectangular opening 142, and a block 144 is formed at each of two sides of the opening 142. In this embodiment, the opening 142 is a connector interface hole.

The protective cover mechanism 20 includes a support member 24 and a protective cover 26. The support member 24 is configured for being latched on the housing 10. The protective cover 26 is rotatably attached to the support member 24 for selectively covering or uncovering the opening 142.

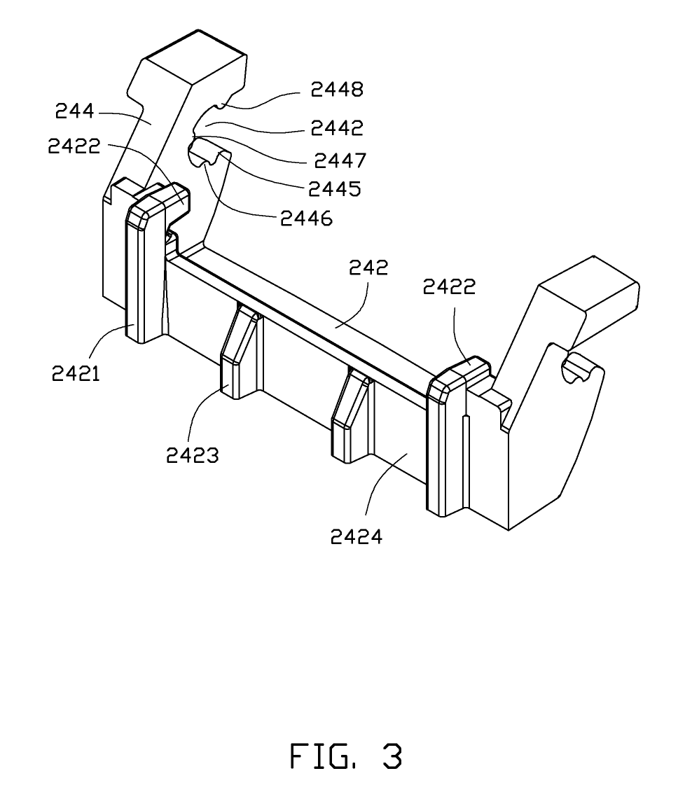

The support member 24 includes a main plate 242 and an arm 244 is formed at each of two sides of the main plate 242. Two beams 2421 and two ribs 2423 extend from one surface of the main plate 242. A protrusion 2422 perpendicularly extends from one end of each beam 2421 for limiting the rotation range of the protective cover 26. The ribs 2423 are formed between and parallel to the two beams 2421. A mating groove 2424 is defined between each beam 2421 and its adjacent rib 2423. When the support member 24 is positioned on the main body 12, a top of each arm 244 is abutted by the blocks 144, and each resisting member 122 is positioned in a corresponding mating groove 2424 for mounting the support member 24 on the housing 10, such as by adhesive or friction fit or heat melting. Referring to FIG. 3, each arm 244 defines a slot 2442 and an entrance 2444 communicating with each other. The slot 2442 is used for rotatably receiving the protective cover 26. A first projection 2445, a second projection 2446, a third projection 2447, and a fourth projection 2448 are formed in a peripheral wall of the slot 2442 for limiting the rotational range of the protective cover 24.

The protective cover 26 includes a cover portion 262 and a flange 264 perpendicularly extends from each of two ends of the cover portion 262. An extending edge 2621 is formed at one side of the cover portion 262 and is configured for being stopped by the protrusion 2422. An axle 266 perpendicularly extends from each flange 264. The axles 266 are coaxial. Each axle 266 includes a plurality of ridges 2662 configured for engaging with the first projection 2445, the second projection 2446, the third projection 2447, and the fourth projection 2448 to retain the protective cover 26 in different degrees of rotation. The protective cover 26 can be made of elastic material for allowing the axle 266 to be deformed relative to the first projection 2445, the second projection 2446, the third projection 2447, and the fourth projection 2448 in each slot 2442. In this embodiment, there are four ridges 2662, and are labeled by 2662a, 2662b, 2662c, 2662d.

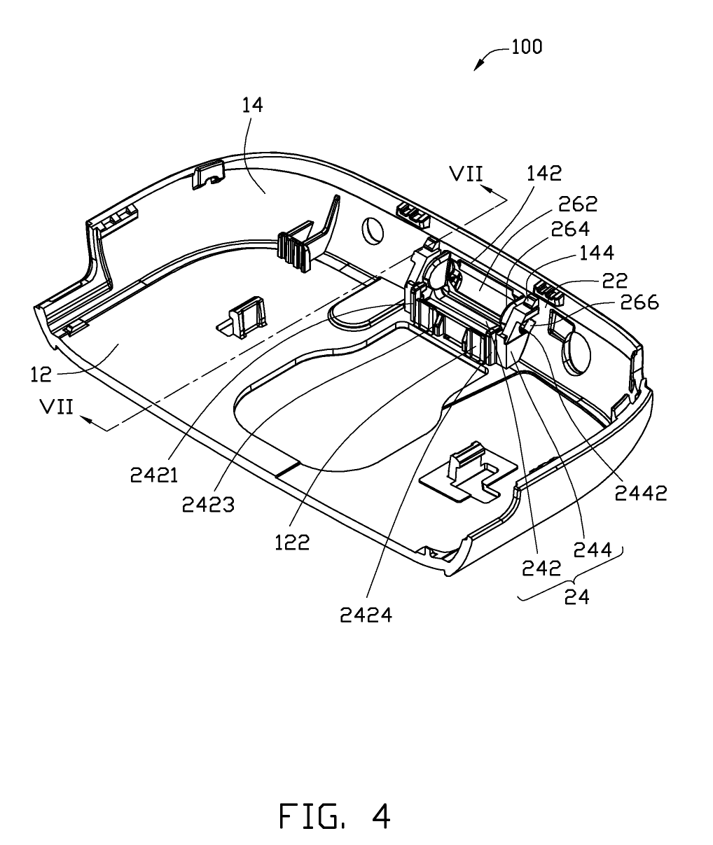

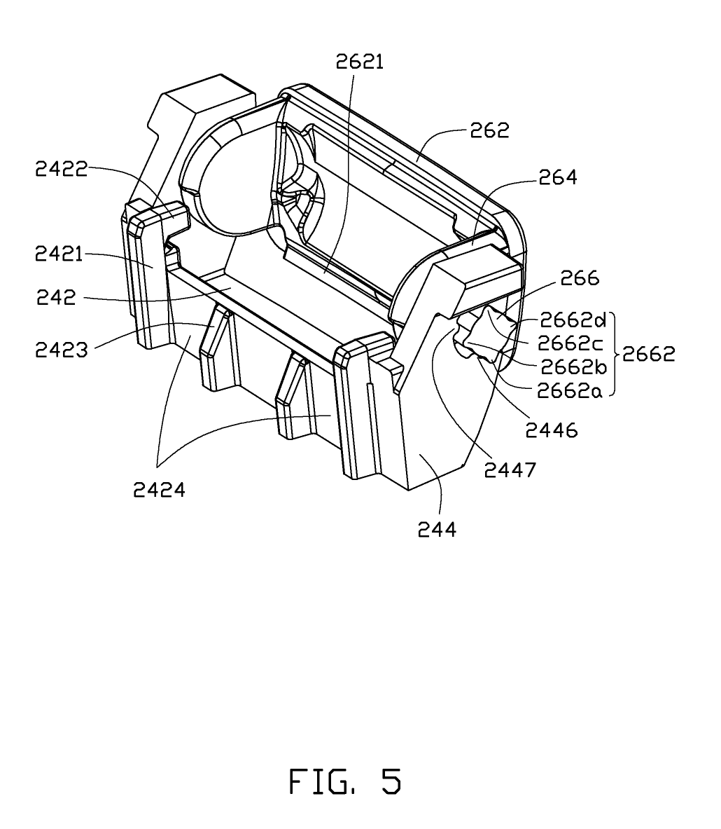

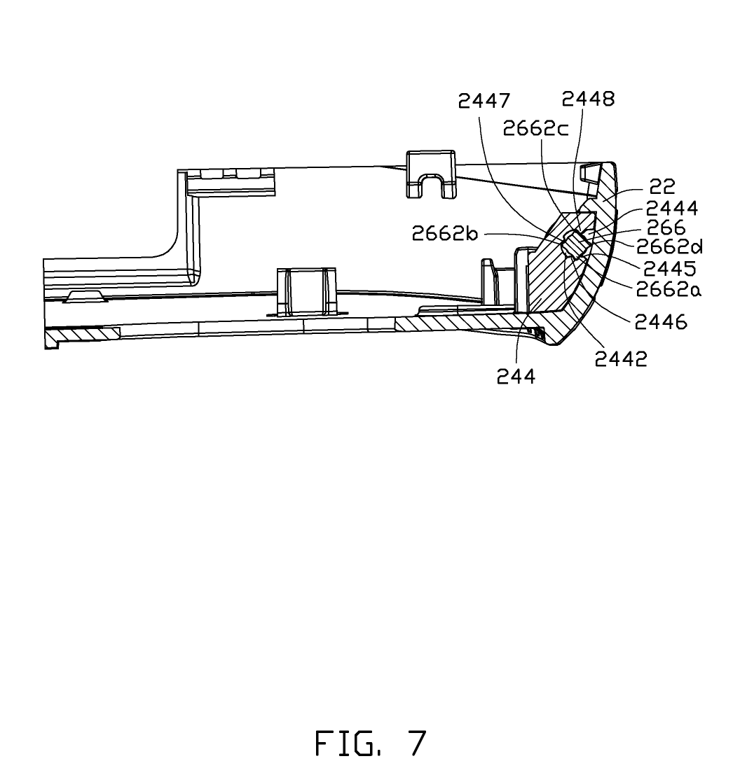

In FIGS. 4, 5 and 7, when the cover mechanism 20 is assembled to the housing 10, the support member 24 is positioned between the sidewall 14 and the resisting members 122. Each resisting member 122 is positioned in a corresponding mating groove 2424 and a top of each arm 244 is abutted by the blocks 144 for mounting the support member 24 on the housing 10. Then, each axle 266 is inserted into a corresponding slot 2442 from the entrance 2444. Each axle 266 is pressed to be retained within the slot 2442. In this embodiment, each axle 266 is pressed to force the ridge 2662a to be retained between the first projection 2445 and the second projection 2446 and the ridge 2662c to be retained by the fourth projection 2448. Thus, the axles are retained within the slot 2442. Accordingly, the protective cover 26 is attached to the support member 24 for covering the opening 142.

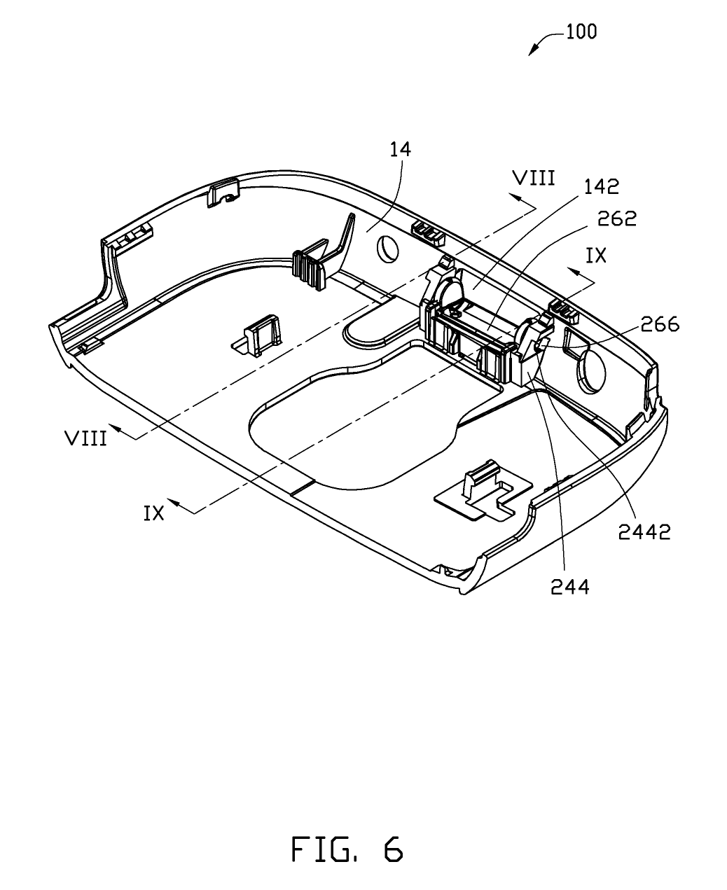

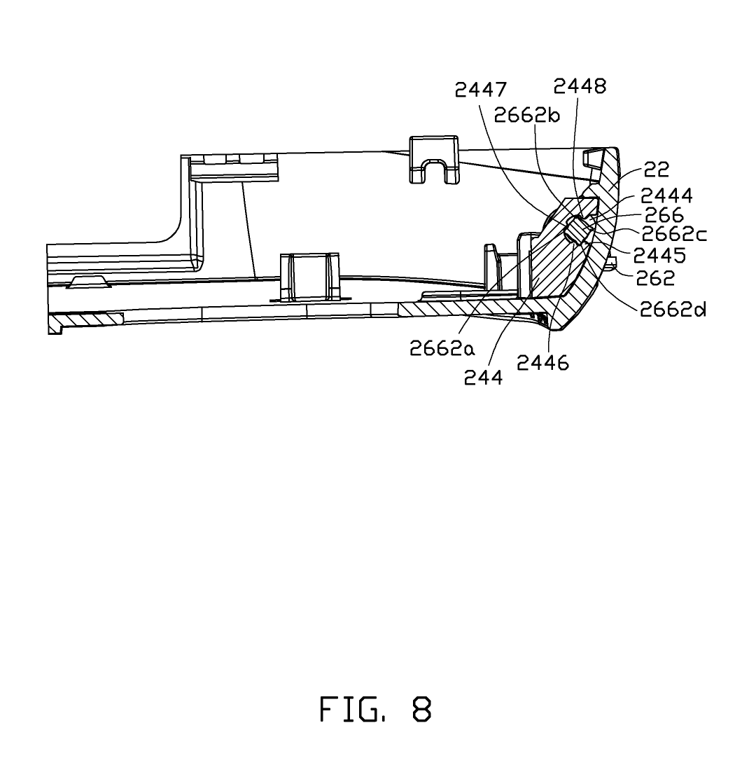

Referring to FIGS. 6 and 8, when the protective cover 26 is to be opened, the operator rotates the cover portion 262 so that the axles 266 rotate along the axis of the slots 2442. During rotation, the ridges 2662 sequentially move between the various projections 2445, 2446, 2447 until the ridges 2662 are positioned at another position to expose the opening 142.

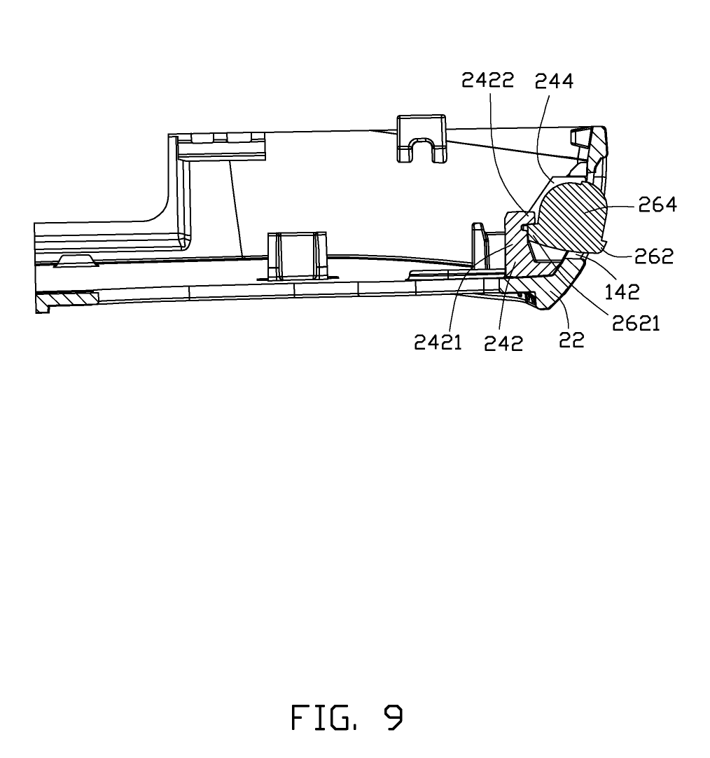

In this embodiment, the ridge 2662d is forced to be retained between the first projection 2445 and the second projection 2446. The ridge 2662a is forced to ride over the second projection 2446, and is retained by the third projection 2447. The ridge 2662b is retained by the fourth projection 2448. The ridge 2262c is rotated to be received in the entrance 2444. Referring to FIG. 9, the cover portion 262 is rotated to make the extending edge 2621 of the cover portion 262 be stopped by the protrusion 2422 for preventing the protective cover 26 from rotating over a desired angle. Accordingly, the opening 142 is exposed from the sidewall 14 for insertion of one of various kinds of plugs.

To close and lock the cover mechanism 20, the above process is reversed and the protective cover 26 moved from the opened position to the closed position with the ridge 2662a abutting between the first projection 2445 and the second projection 2446 and the ridge and the ridge 2662c retained by the fourth projection 2448.

It is to be understood, however, that even through numerous characteristics and advantages of the exemplary disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A cover mechanism for an electronic device, the cover mechanism comprising:
a support member latched to the electronic device, the support member defining two slots, a plurality of projections formed in each slot;
a protective cover including a cover portion, and two axles; the axles rotatably received in the slots, each axle including a plurality of ridges;
wherein the ridges of the protective cover are deformedly latched in the slots to position the protective cover relative to the support member in different positions.

2. The cover mechanism as claimed in claim 1, wherein the support member includes a main plate and two arms formed at each side of the main plate, two mating grooves are defined on the main plate configured for mounting the support member on the electronic device.

3. The cover mechanism as claimed in claim 2, wherein two beams and two ribs extend from one side of the main plate, the two ribs are formed between the two beams, and are parallel with the two beams, each mating groove is defined each beam and each adjacent rib.

4. The cover mechanism as claimed in claim 1, wherein the protective cover includes a cover portion and a flange perpendicularly extending from each of two ends of the cover portion, and each axle perpendicularly extends from each flange.

5. The cover mechanism as claimed in claim 4, wherein a protrusion perpendicularly extends from one end of each beam for limiting a rotation range of the protective cover, an extending edge is formed at one side of the cover portion, and is stopped by the protrusion.

6. A cover mechanism for covering a hole of an electronic device, the cover mechanism comprising:
a housing;
a support member latched on the housing, the support member defining two slots, a plurality of projections formed in each slot;
a protective cover rotatably attached to the support member, the protective cover including two axles; the axles rotatably received in the slots, each axle including a plurality of ridges engaging with the projections for selectively covering or exposing the hole.

7. The cover mechanism as claimed in claim 6, wherein the housing includes a main body and a sidewall extending from a peripheral edge of the main body, two spaced resisting members protrude from the main body, and are spaced from the sidewall, the sidewall defines the hole, and the support member is retained on the resisting members.

8. The cover mechanism as claimed in claim 7, wherein the support member includes a main plate and two arms formed at each side of the main plate, the mating grooves are defined on the main plate for mounting the support member.

9. The cover mechanism as claimed in claim 8, wherein two beams and two ribs extend from one side of the main plate, the two ribs are formed between the two beams, and are parallel with the two beams, and each mating groove is defined each beam and each adjacent rib.

10. The cover mechanism as claimed in claim 8, wherein two blocks are formed at each side of the hole, and a top of each arm is abutted by the blocks.
